(19) United States
(12) Patent Application Publication
(10) Pub. No.: US 2019/0115385 A1
(43) Pub. Date: Apr. 18, 2019

(54) PHOTOELECTRIC CONVERTER AND X-RAY DETECTOR

(71) Applicant: SHARP KABUSHIKI KAISHA, Sakai City, Osaka (JP)

(72) Inventors: HIROYUKI MORIWAKI, Sakai City (JP); KAZUHIDE TOMIYASU, Sakai City (JP); MAKOTO NAKAZAWA, Sakai City (JP); FUMIKI NAKANO, Sakai City (JP); WATARU NAKAMURA, Sakai City (JP)

(73) Assignee: SHARP KABUSHIKI KAISHA, Sakai City, Osaka (JP)

(21) Appl. No.: 16/090,529

(22) PCT Filed: Mar. 30, 2017
(86) PCT No.: PCT/JP2017/013408

§ 371 Date: Oct. 1, 2018

(30) Foreign Application Priority Data
Apr. 1, 2016 (JP) 2016-074729

(51) Int. Cl. H01L 27/146; G01T 1/20

(52) U.S. Cl. CPC H01L 27/14636; H01L 27/14663; G01T 1/2018

(57) ABSTRACT

A photoelectric converter of one aspect of the present invention is provided with an element substrate having a photodiode and a thin film transistor arranged in matrix form, an interlayer insulating film laminated on the thin film transistor, a first contact hole formed in the interlayer insulating film and reaching a surface of a source electrode of the thin film transistor, and a second contact hole formed in the interlayer insulating film and reaching a surface of a drain electrode of the thin film transistor, in which a source bus line and the source electrode of the thin film transistor are connected via the first contact hole, the drain electrode of the thin film transistor and a lower layer electrode of the photodiode are connected via the second contact hole, and the tapered part of the second contact hole has a gentler inclination than the tapered part of the first contact hole.

### TECHNICAL FIELD

Several aspects of the present invention relate to a photoelectric converter and an X-ray detector.

Priority is claimed on Japanese Patent Application No. 2016-074729 filed in Japan on Apr. 1, 2016, the content of which is incorporated herein by reference.

### BACKGROUND ART

In the related art, as one method of increasing the output performance of a photosensor, there is a method for increasing a ratio of the area of a silicon (Si) layer of a photodiode. For example, in PTL 1, the photodiode has a shape which includes a contact hole which is a diode bottom contact opening. However, since the silicon layer constituting the photodiode is formed to straddle an edge of the contact hole, a step is generated and the step coverage deteriorates at the time of silicon film formation. Due to this, there is a problem in that leakage current (dark current) increases, which lowers the sensitivity of the photosensor.

As means for solving the above, PTL 2 discloses that the photodiode is formed inside the opening edge of the contact hole and inside the pattern of the drain electrode.

In PTL 1, in order to increase quantum efficiency, the photodiode includes a contact hole and a thin film transistor, and the diode area is increased. However, a step is generated in the contact hole and the leakage current increases.

On the other hand, in PTL 2, since the thin film transistor and the contact are formed outside the photodiode, although the performance is improved in relation to the leakage current, the diode area is reduced, and there is a trade-off relationship between the two.

### CITATION LIST

### Patent Literature

PTL 1: Japanese Unexamined Patent Application Publication No. 2003-158253

PTL 2: Japanese Unexamined Patent Application Publication No. 2008-283113

### SUMMARY OF INVENTION

### Technical Problem

However, although the performance is improved in relation to the leakage current in PTL 2, since the thin film transistor and a part of the contact are formed outside the photodiode, the ratio of the area of the silicon layer decreases. Due to this, there is a trade-off problem in that, conversely, the performance deteriorates in relation to the quantum efficiency.

The problem described above is caused by the fact that it is not possible to increase the area of the photodiode and reduce the step of the contact hole at the same time.

An aspect of the present invention is made in consideration of the above-described problems of the related art and has an object of providing a photoelectric converter and an X-ray detector capable of reducing leakage current without reducing a ratio of an area of a silicon layer in a photodiode.

### Solution to Problem

A photoelectric converter according to an aspect of the present invention includes an element substrate having a photodiode and a thin film transistor arranged in matrix form, an interlayer insulating film laminated on the thin film transistor, a first contact hole formed in the interlayer insulating film and reaching a surface of a source electrode of the thin film transistor, and a second contact hole formed in the interlayer insulating film and reaching a surface of a drain electrode of the thin film transistor, in which a source bus line and the source electrode of the thin film transistor are connected via the first contact hole, the drain electrode of the thin film transistor and a lower layer electrode of the photodiode are connected via the second contact hole, and a tapered part of the second contact hole has a gentler inclination than a tapered part of the first contact hole.

A photoelectric converter according to another aspect of the present invention includes an element substrate having a photodiode and a thin film transistor arranged in matrix form, an interlayer insulating film laminated on the thin film transistor, a second contact hole formed in the interlayer insulating film and reaching a surface of a drain electrode of the thin film transistor, and a third contact hole formed in the interlayer insulating film and reaching a surface of a gate electrode of the thin film transistor, in which the drain electrode of the thin film transistor and a lower layer electrode of the photodiode are connected via the second contact hole, the gate electrode of the thin film transistor and a gate bus line are connected via the third contact hole, and a tapered part of the second contact hole has a gentler inclination than a tapered part of the third contact hole.

In addition, in the photoelectric converter according to the aspect of the present invention, a tapered shape of the second contact hole may be gently inclined by 1.5 times or more than a tapered shape of the first contact hole or the third contact hole.

In addition, in the photoelectric converter according to the aspect of the present invention, an inclination angle θ of the tapered part of the second contact hole may be approximately 50° or less.

In addition, in the photoelectric converter according to the aspect of the present invention, the tapered part of the second contact hole may have an aspect ratio of 2:1 for opening depth to opening width.

In addition, in the photoelectric converter according to the aspect of the present invention, a step portion may be provided in a tapered shape of the second contact hole.

In addition, in the photoelectric converter according to the aspect of the present invention, the interlayer insulating film may be a planarization layer having a film thickness of 1 μm or more.

In addition, in the photoelectric converter according to the aspect of the present invention, the interlayer insulating film may be an organic insulating film.

In addition, in the photoelectric converter according to the aspect of the present invention, the interlayer insulating film may be a photosensitive acrylic insulating film.

In addition, in the photoelectric converter according to the aspect of the present invention, the thin film transistor may overlap the photodiode in plan view.

In addition, in the photoelectric converter according to the aspect of the present invention, a portion of the interlayer insulating film positioned between the thin film transistor and the photodiode may be flat.

In addition, in the photoelectric converter according to the aspect of the present invention, the photodiode may be a PIN diode.

An X-ray detector according to still another aspect of the present invention includes a scintillator which converts X-rays into visible light, and the photoelectric converter described above.

### Advantageous Effects of Invention

According to the aspects of the present invention, it is possible to provide a photoelectric converter capable of reducing leakage current without reducing a ratio of an area of a silicon layer in a photodiode.

### BRIEF DESCRIPTION OF DRAWINGS

FIG. 1 is an equivalent circuit diagram of the photoelectric converter of the first embodiment.

FIG. 2 is a plan view showing a configuration of one pixel in the photoelectric converter of the first embodiment.

FIG. 3 is a sectional view taken along line A-A of FIG. 2.

FIG. 4 is a plan view showing a configuration of a thin film transistor in the photoelectric converter of the second embodiment.

FIG. 5 is a sectional view taken along line B-B of FIG. 4.

FIG. 6 is a plan view showing a configuration of a thin film transistor in a photoelectric converter of a third embodiment.

FIG. 7 is a sectional view taken along line C-C of FIG. 6.

FIG. 8 is a sectional view taken along line D-D of FIG. 6.

FIG. 9 is a view for illustrating a configuration of an X-ray detector according to one embodiment of the present invention.

### DESCRIPTION OF EMBODIMENTS

### First Embodiment

A description will be given below of a photoelectric converter of a first embodiment of the present invention.

In the following drawings, in order to make each component easy to view, the scale of the dimensions may be made different depending on the components.

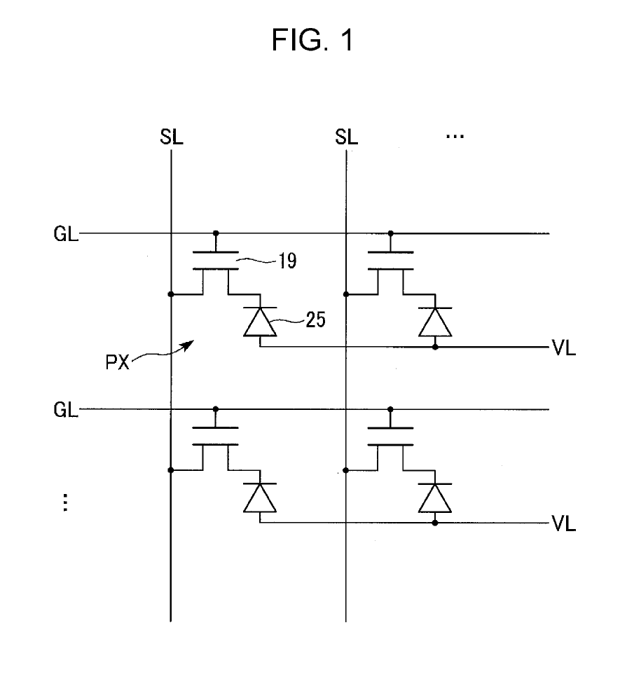

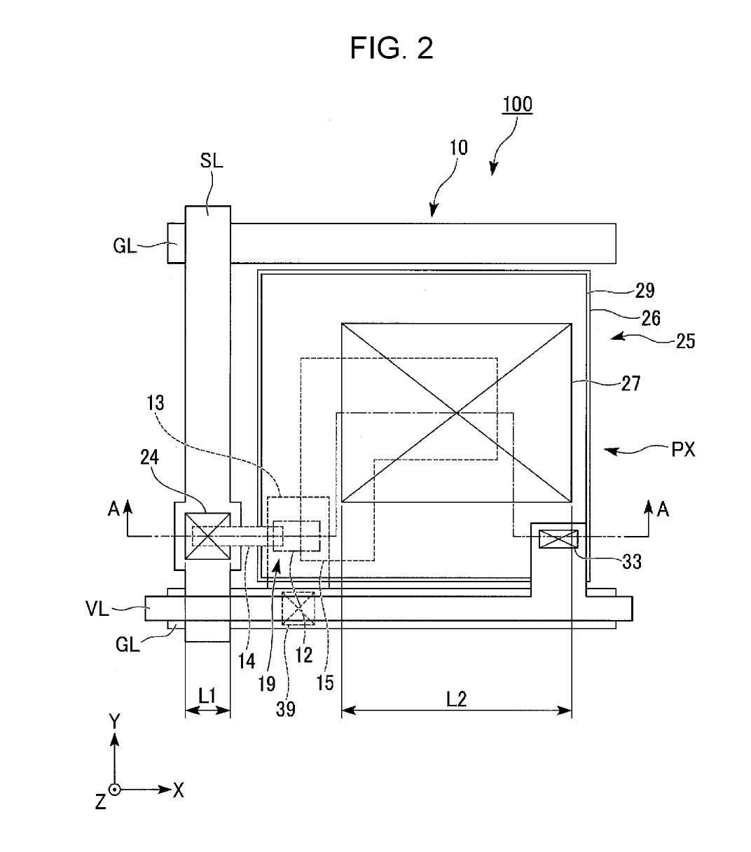

FIG. 1 is an equivalent circuit diagram of a photoelectric converter 100 of the first embodiment. FIG. 2 is a plan view showing a configuration of one pixel in the photoelectric converter 100 of the first embodiment.

As shown in FIG. 1, the photoelectric converter 100 has an element substrate 10 in which a plurality of pixels PX are arranged in a matrix form. On the element substrate 10, a plurality of source bus lines SL, SL . . . are provided so as to extend in parallel to each other. On the element substrate 10, a plurality of gate bus lines GL, GL . . . are provided so as to extend in parallel to each other. The plurality of gate bus lines GL, GL . . . are orthogonal to the plurality of source bus lines SL, SL . . . On the element substrate 10, the plurality of gate bus lines GL and the plurality of source bus lines SL are provided in a lattice shape. A rectangular region partitioned by two adjacent source bus lines SL and two adjacent gate bus lines GL becomes one pixel PX.

As shown in FIG. 1 and FIG. 2, the photoelectric converter 100 of the present embodiment is configured to be provided with a thin film transistor 19 and a photodiode 25 in one pixel PX. The source bus line SL is connected to a source electrode 14 of the thin film transistor 19. The gate bus line GL is connected to a gate electrode 13 of the thin film transistor 19.

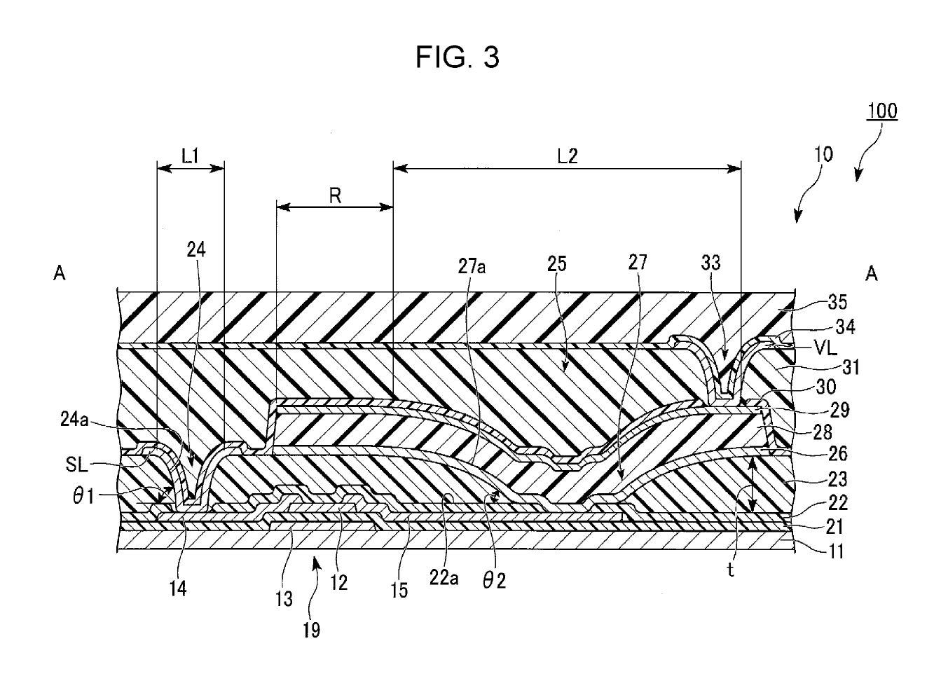

FIG. 3 is a sectional view taken along line A-A of FIG. 2.

In addition, Table 1 shows specific examples of each component. In the following description, Table 1 will be referred to as appropriate.

TABLE 1

| | Material | Film Thickness [nm] | Notes |
|---|---|---|---|
| Gate wiring | Tungsten-based | 200-500 | May be a laminated film |
| Gate insulating film | Gate insulating film | 300-500 | May be a laminated film |
| | (SiO₂, SiN, and the like) | | |
| Channel layer | IGZO | | |
| Source electrode | Aluminum-based | 300-800 | May be a laminated film |
| First interlayer insulating film | SiO₂, SiN, and the like | 300-600 | May be a laminated film |
| First planarization film | Photosensitive acrylic resin | 1000-3000 | |
| Diode lower layer electrode | Aluminum-based | 300-800 | May be a laminated film |
| Diode | Transparent electrode/P+/i layer/n+ | 20-300/5-30/800-1500/10-50 | May be a laminated film |
| Second interlayer insulating film | SiO₂, SiN, and the like | 200-500 | May be a laminated film |
| Second planarization film | Photosensitive acrylic resin | 1000-3000 | |
| Bias line | Aluminum-based | 300-800 | May be a laminated film |
| Third interlayer insulating film | SiO₂, SiN, and the like | 100-500 | May be a laminated film |
| Third planarization film | Photosensitive acrylic resin | 1000-3000 | |

As shown in FIG. 3, the thin film transistor 19 having a semiconductor layer 12, the gate electrode 13, the source electrode 14, a drain electrode 15, and the like is formed on an insulating substrate 11. For the insulating substrate 11, for example, it is possible to use a transparent glass substrate.

On one surface side of the insulating substrate 11, the gate electrode 13 formed of metal is formed. As the material of the gate electrode 13, for example, a laminated film of W (tungsten)/TaN (tantalum nitride), Mo (molybdenum), Ti (titanium), Al (aluminum), or the like is used. The film thickness of the gate electrode 13 is, for example, 200 nm to 500 nm as shown in Table 1.

Furthermore, a gate insulating film 21 is formed so as to cover a part of the surface of the gate electrode 13 and a part of the surface of the insulating substrate 11. As the material of the gate insulating film 21, for example, a silicon oxide film, a silicon nitride film, a laminated film thereof, or the like is used. The film thickness of the gate insulating film 21 is, for example, as shown in Table 1, 300 nm to 500 nm.

On the surface of the gate insulating film 21, the semiconductor layer 12 is formed at a position overlapping the gate electrode 13 in plan view. The semiconductor layer 12 is formed of a semiconductor material such as IGZO.

On the gate insulating film 21, the source electrode 14 and the drain electrode 15 are formed so as to partially overlay the semiconductor layer 12. The source electrode 14 is connected to the source region of the semiconductor layer 12. In the same manner, the drain electrode 15 is connected to the drain region of the semiconductor layer 12. As the material of the source electrode 14 and the drain electrode 15, a conductive material similar to that of the gate electrode 13 described above is used. In the present embodiment, the source electrode 14 and the drain electrode 15 are formed using an Al-based material and have a film thickness of 300 nm to 800 nm, for example, as shown in Table 1.

On the gate insulating film 21, the gate bus line GL is further formed in the same layer as the source electrode 14 and the drain electrode 15. The gate bus line GL is connected to the gate electrode 13 on the lower layer side via a contact hole 39 (FIG. 2) formed in the gate insulating film 21. The gate bus line GL is pattern-formed at the same time as the source electrode 14 and the drain electrode 15. Since the resistance of the gate electrode 13 is high, forming the gate bus line GL in the same metal layer as the source electrode 14 having a low resistance makes it possible to suppress the generation of noise and the like.

On the gate insulating film 21, the first interlayer insulating film 22 is formed so as to cover the drain electrode 15 and the source electrode 14. As the material of the first interlayer insulating film 22, the same material as that of the gate insulating film described above or an organic insulating material is used. The film thickness of the first interlayer insulating film 22 is, for example, 300 nm to 600 nm as shown in Table 1.

A first planarization layer 23 having a prescribed film thickness (1 μm to 3 μm) is provided on the first interlayer insulating film 22.

The first planarization layer 23 is formed of a photosensitive acrylic resin film or an organic insulating film and has a first contact hole 24 and a second contact hole 27 which are opened by exposure and development. The first contact hole 24 is a through hole which reaches the surface of the source electrode 14. The second contact hole 27 is a through hole which reaches the surface of the drain electrode 15.

The first planarization layer 23 is formed as a film using a CVD film forming apparatus. Therefore, in a case of being formed of an inorganic insulating film, the film forming time becomes long. On the other hand, in a case of coating-type Spin-On-Glass (SOG), for example, an organic insulating film, film formation in a short time is possible and the planarizing property is also good. In addition, in a case of a photosensitive acrylic resin film, there is an advantage in that shape processing by development is possible.

On the first planarization layer 23, a source bus line SL and a lower layer electrode 26 of the photodiode 25 are formed. The lower layer electrode 26 is formed using an Al-based material and has a film thickness of 300 nm to 800 nm.

The source bus line SL is connected to the source electrode 14 of the thin film transistor 19 via the first contact hole 24 penetrating the first planarization layer 23 and the first interlayer insulating film 22.

The lower layer electrode 26 of the photodiode 25 is connected to the drain electrode 15 of the thin film transistor 19 via the second contact hole 27 penetrating the first planarization layer 23 and the first interlayer insulating film 22. On the lower layer electrode 26, a semiconductor laminated portion 28 is formed.

The semiconductor laminated portion 28 has a structure in which an N-type or P-type semiconductor layer, an intrinsic semiconductor layer, and an N-type or P-type semiconductor layer are laminated in this order. For example, as shown in Table 1, regarding the film thickness of the semiconductor layer, the film thickness of the P-type semiconductor layer is 5 nm to 30 nm, the film thickness of the intrinsic semiconductor layer is 800 nm to 1500 nm, and the film thickness of the N-type semiconductor layer is 10 nm to 50 nm (none of the above are shown in the diagrams).

An upper layer electrode 29 of the photodiode 25 is formed on the surface of the semiconductor laminated portion 28. The upper layer electrode 29 is formed of a transparent electrode such as ITO or IZO and has a film thickness of 20 nm to 300 nm as shown in Table 1, for example.

After forming the thin film transistor 19 on the insulating substrate 11, the photodiode 25 is formed to be laminated on the thin film transistor 19 using a well-known method. The photodiode 25 is arranged outside the opening edge of the first contact hole 24. Laminating the photodiode 25 on the thin film transistor 19 makes it possible to increase the aperture ratio of the photodiode 25 in one pixel PX.

Here, in the first planarization layer 23, a region R in which the thin film transistor 19 and the photodiode 25 overlap in plan view outside the second contact hole 27 has a flat surface.

A second interlayer insulating film 30 is formed on the first planarization layer 23 so as to cover the source bus line SL and the upper layer electrode 29. For the second interlayer insulating film 30, the same insulating material as that of the first interlayer insulating film 22 described above is used. The film thickness of the second interlayer insulating film 30 is 200 nm to 500 nm.

A second planarization layer 31 having a film thickness of 1 μm to 3 μm is formed on the second interlayer insulating film 30 to diminish the steps between various wirings and electrodes on the insulating substrate 11. The second planarization layer 31 is formed of a photosensitive acrylic resin in the same manner as the first planarization layer 23 described above.

On the surface of the second planarization layer 31, a bias line VL is further formed. The bias line VL is connected to the upper layer electrode 29 of the photodiode 25 via a bias line contact hole 33 formed in the second interlayer insulating film 30 and the second planarization layer 31.

As shown in FIG. 2, the bias line VL extends parallel to the gate bus line GL and is formed by being laminated on the gate bus line GL so as to overlap with the gate bus line GL in plan view.

The bias line VL is formed using an Al-based material and is connected to the upper layer electrode 29 of the photodiode 25 via the bias line contact hole 33 penetrating the second planarization layer 31 and the second interlayer insulating film 30. The film thickness of the bias line VL is, for example, 300 nm to 800 nm as shown in Table 1.

A third interlayer insulating film 34 and a third planarization layer 35 are laminated in this order on the second planarization layer 31 so as to cover the bias line VL. The third interlayer insulating film 34 is formed using an insulating material similar to that of the first interlayer insulating film 22 described above and has a film thickness of 100 nm to 500 nm, for example, as shown in Table 1. The third planarization layer 35 is formed using a photosensitive acrylic resin in the same manner as the first planarization layer 23 described above and has a film thickness of 1 μm to 3 μm, for example, as shown in Table 1.

Next, a description will be given of characteristic parts of the present embodiment.

In the photoelectric converter 100 of the present embodiment, the thin film transistor 19 and the photodiode 25 are arranged in a laminated state in one pixel PX. As shown in FIG. 2 and FIG. 3, the photodiode 25 is formed to be laminated on the thin film transistor 19 so as to straddle the opening edge of the second contact hole 27 connecting the lower layer electrode 26 of the photodiode 25 and the drain electrode 15 of the thin film transistor 19.

In the photoelectric converter 100 of the present embodiment, the first contact hole 24 connecting the source bus line SL and the source electrode 14 of the thin film transistor 19 and the second contact hole 27 connecting the lower layer electrode 26 of the photodiode 25 and the drain electrode 15 of the thin film transistor 19 have different tapered shapes. As shown in FIG. 3, a tapered part 27a of the second contact hole 27 is formed with a gentler inclination than a tapered part 24a of the first contact hole 24. That is, the relationship between the inclination angle θ1 of the tapered part 24a of the first contact hole 24 and the inclination angle θ2 of the tapered part 27a of the second contact hole 27 satisfies the relationship θ2<θ1.

Here, the inclination angle θ1 described above is the angle between the surface of the first interlayer insulating film 22 and the tapered part 24a which is a side wall surface of the first contact hole 24. In addition, the inclination angle θ2 is the angle between a surface 22a of the first interlayer insulating film 22 and the tapered part 27a which is a side wall surface of the second contact hole 27.

In a case where the tapered shape of the second contact hole 27 is steep, a step is generated due to the opening edge of the second contact hole 27 in the forming region of the photodiode 25. The dark current (leakage current) of the photodiode 25 increases due to the step coverage in the contact hole portion, and the performance of the photodiode 25 deteriorates.

Therefore, in the present embodiment, the tapered shape in the second contact hole 27 is made to be gentle and the step caused by the opening edge of the second contact hole 27 is diminished in the formation region of the photodiode 25. Specifically, the inclination angle of the tapered part 27a in the second contact hole 27 is set to approximately 45° to 50° or less, the aspect ratio of the opening depth t to the opening width L2 is set to 2:1 or more, and the tapered part 27a of the second contact hole 27 is formed to have a gentle inclination.

Then, the opening width L2 in the X direction of the second contact hole 27 connecting the lower layer electrode 26 of the photodiode 25 and the drain electrode 15 of the thin film transistor 19 is 1.5 times or more larger than the opening width L1 in the X direction of the first contact hole 24 connecting the source bus line SL and the source electrode 14 of the thin film transistor 19, and it is possible to set the tapered shape of the second contact hole 27 to a gentler inclination than that of the tapered shape of the first contact hole 24.

Due to this, in the forming region of the photodiode 25, the step due to the second contact hole 27 is reduced and an increase in the leakage current is suppressed. In addition, forming the photodiode 25 on the thin film transistor 19 in a laminated manner makes it possible to suppress decreases in the ratio of the forming region of the photodiode 25 (the forming area of the semiconductor structure including the Si layer) in one pixel PX.

Here, for example, in a case where the tapered shape of the contact hole connecting the source bus line SL and the source electrode 14 is gentle, the wiring width of the source bus line SL becomes thin due to the influence of the tapered shape of the contact hole, and there is a concern that there will be a problem such as an increase in the wiring resistance value or a deterioration in the performance of the read-out signal from the photodiode 25. Therefore, when the wiring width of the source bus line SL in the contact region is increased in order to suppress the narrowing of the wiring width of the source bus line SL, this causes a decrease in the aperture ratio of the photodiode 25 in one pixel PX. For this reason, it is suitable if the tapered shape of the first contact hole 24 on the side of the source bus line SL is steep.

In addition, as one method of improving the aperture ratio of the photodiode 25, for example, suppressing the wiring width of the source bus line SL in the contact region may be considered; however, as described above, there is a limitation in consideration of increasing the wiring resistance value, deteriorating the performance of the read-out signal from the photodiode, and the like.

For example, in a case where the film thickness of the first planarization layer 23 is 2 μm to 3 μm and, for example, when the inclination angle θ1 of the tapered part 24a of the first contact hole 24 is approximately 75°, it is possible to suppress the wiring width in the contact portion of the source bus line SL to approximately 5 μm to 8 μm. However, the dark current of the photodiode 25 increases.

As another method of improving the aperture ratio of the photodiode 25, in the present embodiment, a configuration is adopted in which the second contact hole 27 connecting the lower layer electrode 26 of the photodiode 25 and the drain electrode 15 of the thin film transistor 19 is arranged at a position to overlap the photodiode 25 in plan view. This configuration also makes it possible to improve the connection reliability in the contact region without inviting a decrease in the aperture ratio of the photodiode 25, which is effective in a configuration in which the thin film transistor 19 and the photodiode 25 are arranged in one pixel PX.

In the present embodiment, the first planarization layer 23 laminated on the thin film transistor 19 and the second planarization layer 31 laminated on the photodiode 25 each have a film thickness of 1 μm or more. Due to this, it is possible to reduce the step above the thin film transistor 19 and the photodiode 25 and to prevent deterioration in the performance of the photodiode 25.

In addition, in each of the first planarization layer 23 and the second planarization layer 31, it is possible to reduce the capacitance between the vertically laminated wirings and electrodes and between the photodiode 25 and the thin film transistor 19.

As described above, according to the photoelectric converter 100 of the present embodiment, it is possible to simultaneously realize both of an increase in the forming area of the photodiode 25 (the forming area of the semiconductor laminated portion 28 including the Si layer) in one pixel PX and a reduction in the step due to the second contact hole 27 in the forming region of the photodiode 25. For this reason, it is possible to increase the quantum efficiency, the increase in the leakage current is suppressed, and it is possible to improve the performance of the photodiode 25.

In the present embodiment, when forming each of the first contact hole 24 and the second contact hole 27 in the first planarization layer 23, using a multi-gradation mask such as a gray tone mask or a half exposure mask makes it possible to simultaneously form the first contact hole 24 and the second contact hole 27 having different tapered shapes.

### Second Embodiment

Next, a description will be given of a photoelectric converter 200 according to a second embodiment of the present invention.

The basic configuration of the photoelectric converter 200 of the present embodiment described below is substantially the same as that of the first embodiment described above but differs in the tapered shape of the second contact hole 27. Therefore, in the following description, different portions will be described in detail and description of common portions will be omitted. In addition, in each drawing used for explanation, the same reference numerals are given to the components common to those in FIG. 1 to FIG. 3.

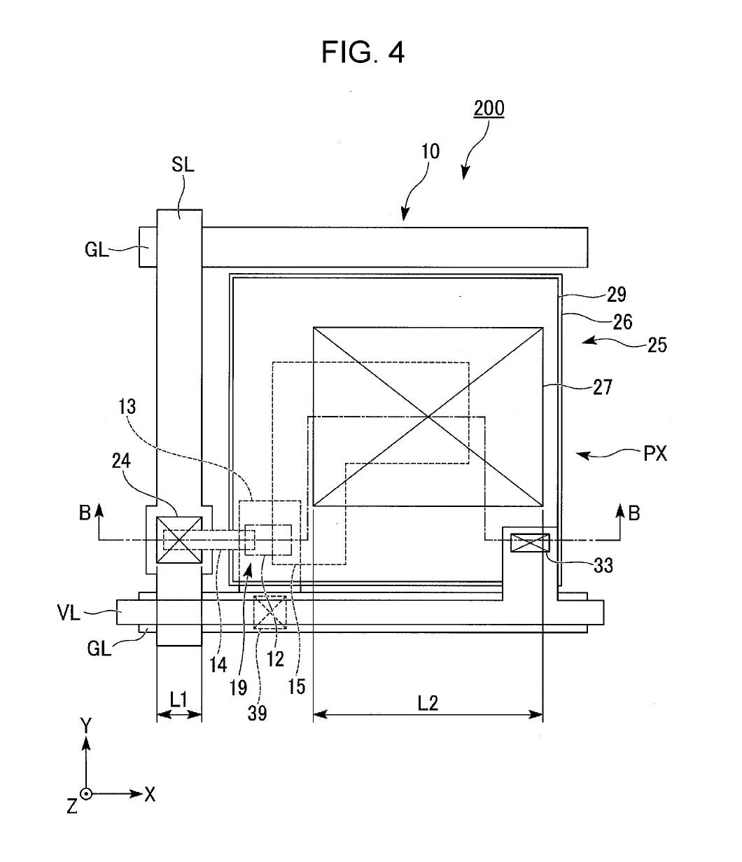

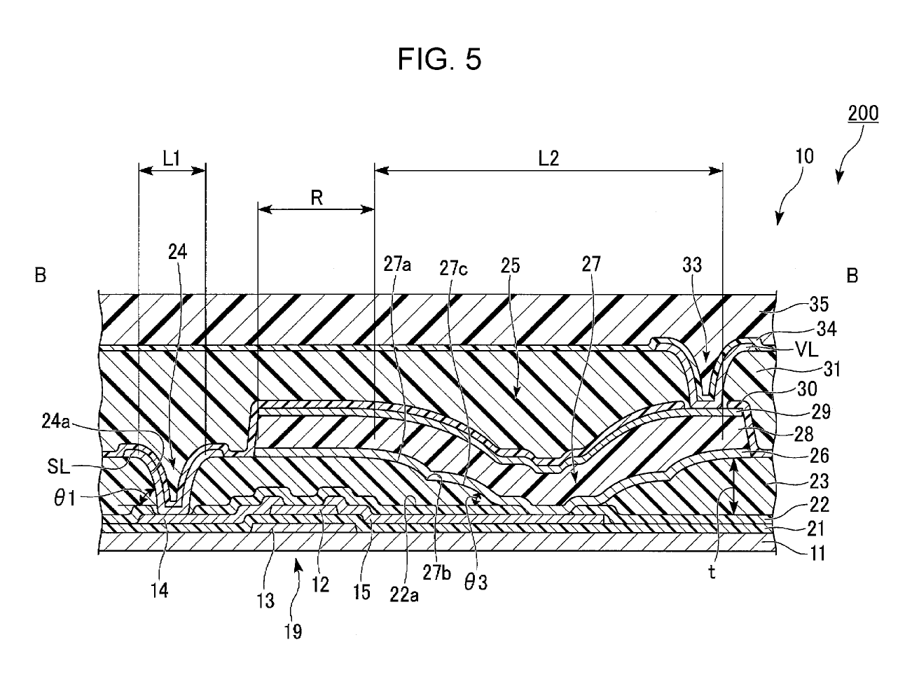

FIG. 4 is a plan view showing a configuration of the thin film transistor 19 in the photoelectric converter 200 of the second embodiment. FIG. 5 is a sectional view taken along line B-B of FIG. 4.

As shown in FIG. 4 and FIG. 5, in the photoelectric converter 200 according to the present embodiment, a step portion 27b is provided substantially in the middle of the tapered part 27a of the second contact hole 27. It is possible to form the second contact hole 27 by exposing the first planarization layer 23 using a halftone mask.

In the tapered part 27a of the second contact hole 27 shown in FIG. 5, the inclination angle θ3 between an inclined surface 27c closer to the insulating substrate 11 side than the step portion 27b and the surface 22a of the first interlayer insulating film 22 is smaller than the inclination angle θ2 shown in FIG. 3 in the first embodiment (θ3<θ2).

That is, providing the step portion 27b in the tapered part 27a of the second contact hole 27 and setting the inclination in the tapered shape in two steps makes it possible to allow the tapered part 27a to have a gentler inclination angle.

### Third Embodiment

Next, a description will be given of a photoelectric converter 300 according to a third embodiment of the present invention.

The basic configuration of the photoelectric converter 300 of the present embodiment described below is substantially the same as that of the first embodiment but differs in the point that a third contact hole 37 is further provided. Therefore, in the following description, different portions will be described in detail, and description of common portions will be omitted. In addition, in each drawing used for explanation, the same reference numerals are given to the components common to those in FIG. 1 to FIG. 3.

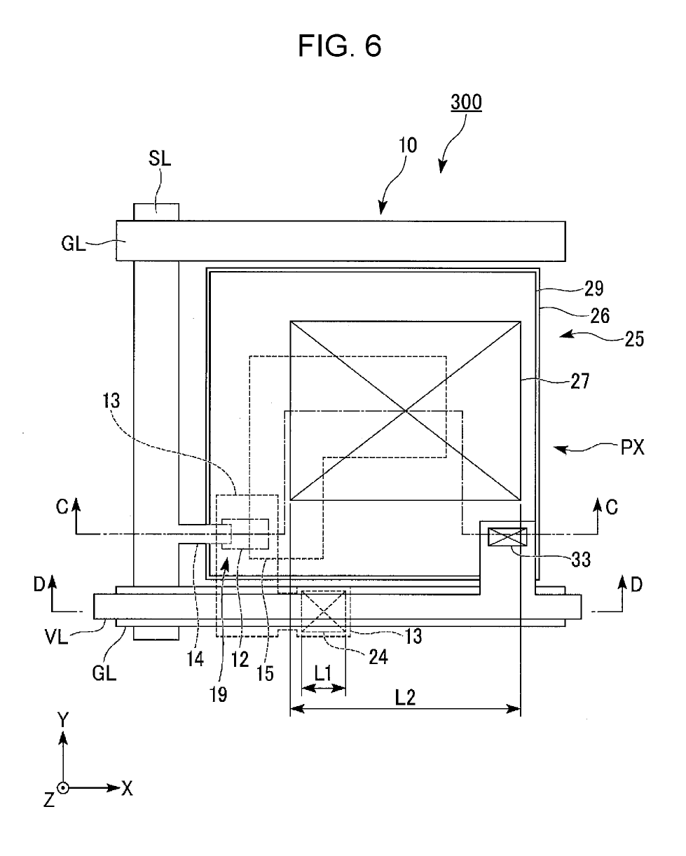

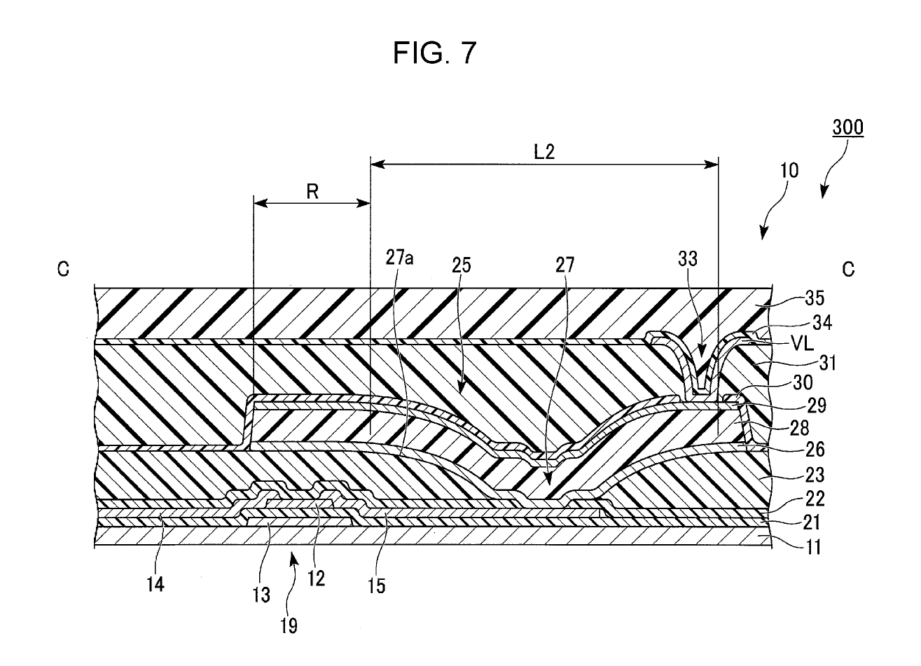

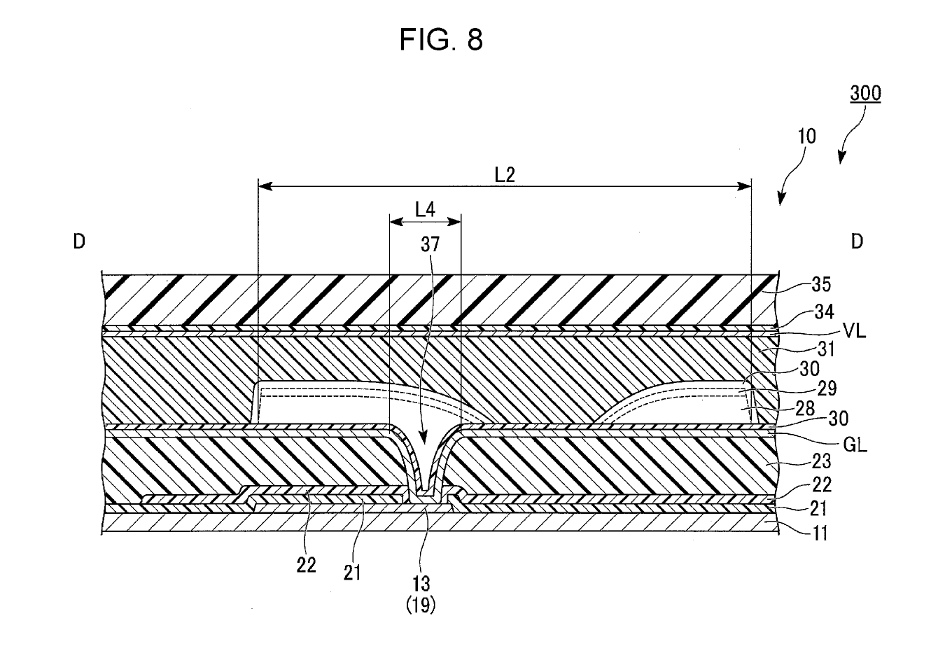

FIG. 6 is a plan view showing the configuration of the thin film transistor 19 in the photoelectric converter 300 of the third embodiment. FIG. 7 is a sectional view taken along line C-C of FIG. 6. FIG. 8 is a sectional view taken along line D-D of FIG. 6.

In the photoelectric converter 300 according to the present embodiment, as shown in FIG. 6 and FIG. 8, the gate electrode 13 constituting the thin film transistor 19 is formed to straddle from a region overlapping the semiconductor layer 12 to a region overlapping the gate bus line GL in plan view. In the previous embodiment, the gate bus line GL was formed in the same layer as the source electrode 14; however, the present embodiment differs in the point that the gate bus line GL is formed in the same layer as the lower layer electrode 26.

As shown in FIG. 8, the gate bus line GL is formed on the surface of the first planarization layer 23 covering the thin film transistor 19. The third contact hole 37 which reaches the surface of the gate electrode 13 positioned in the lower layer is formed in the first planarization layer 23, the first interlayer insulating film 22, and the gate insulating film 21, and the gate bus line GL and the gate electrode 13 are connected via the third contact hole 37. A second interlayer insulating film 30 is formed on the gate bus line GL.

Also in the configuration of the present embodiment, it is possible to set the opening width L2 of the second contact hole 27 on the photodiode 25 side to a length of 1.5 times or more the opening width L4 of the third contact hole 37 on the gate electrode side.

### [X-ray Detector]

Next, a description will be given of an X-ray detector 400 provided with a photoelectric converter according to an embodiment of the present invention.

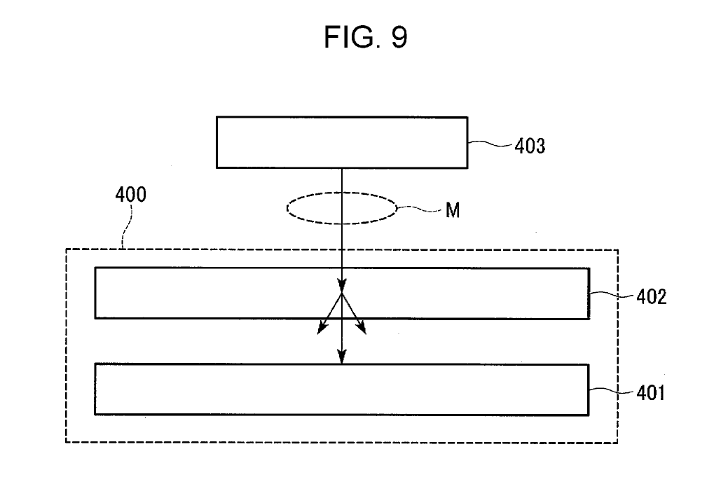

FIG. 9 is a diagram for illustrating a configuration of the X-ray detector 400 according to an embodiment of the present invention.

As shown in FIG. 9, the X-ray detector 400 is formed to have a scintillator 402 which converts X-rays into light and a photosensor 401 which detects light. The photosensor 401 and the scintillator 402 are arranged at prescribed intervals from each other and these arrangement intervals are uniform in order to increase the resolution of the X-ray detector 400.

An inspection object M such as a patient is located between the X-ray detector 400 and an X-ray source 403 and, when X-rays emitted from the X-ray source 403 pass through the inspection object M and are incident to the scintillator 402 of the X-ray detector 400, the scintillator 402 emits light. The light emitted from the scintillator 402 is received by the photosensor 401, and an X-ray image is imaged. At this time, it is effective for the photosensor 401 to have a configuration in which a plurality of pixels are arranged in a matrix form in row and column directions.

As the photosensor 401, any one of the photoelectric converters 100, 200, and 300 of the respective embodiments described above is used. The photodiode 25 described above is a photoelectric conversion element which generates current when irradiated with light. Accordingly, a photocurrent flows through the photodiode 25 when the light emitted from the scintillator 402 is detected.

Here, making the interval between the photosensor 401 and the scintillator 402 constant makes it possible for the light converted by the scintillator 402 to be uniformly incident on the photosensor 401. The light converted by the scintillator 402 being uniformly incident to the photosensor 401 makes it possible to increase the resolution of the photosensor 401.

The scintillator 402 may be a scintillator layer. The scintillator 402 converts radiation into light which the photoelectric conversion element (photodiode 25) is able to sense, and has a structure having a plurality of columnar crystals. In the scintillator 402 having columnar crystals, since the light generated in the scintillator 402 propagates in the columnar crystals, there is little light scattering and it is possible to improve the resolution. As the material of the scintillator 402 forming the columnar crystal, a material containing an alkali halide as a main ingredient is suitably used. For example, CsI:Tl, CsI:Na, CsBr:Tl, NaI:Tl, LiI:Eu, KI:Tl, or the like are used. As a preparation method thereof, for example, it is possible to form the scintillator 402 by simultaneously depositing the CsI and Tl in the CsI:Tl.

As the material of the scintillator 402, generally, cesium iodide (CsI):sodium (Na), cesium iodide (CsI):thallium (TI), sodium iodide (NaI), gadolinium oxysulfide (Gd₂O₂S), and the like are used, and forming grooves by dicing or the like or performing deposition to form a columnar structure using a vapor deposition method makes it possible to improve the resolution performance. Examples of other materials for the scintillator 402 include a-Se, Si, CdTe, CdZnTe, HgI₂, PbI₂, and the like.

In addition, the photosensor 401 and the scintillator 402 may be configured to be provided on the same substrate.

For example, the scintillator 402 formed of CsI and which converts X-rays to visible light may be deposited by a known method on the third planarization layer 35 in the element substrate 10 shown in FIG. 3.

While suitable embodiments according to the present invention were described above with reference to the accompanying drawings, it is needless to say that the present invention is not limited to such examples. It will be apparent to persons skilled in the art that various modifications or improvements may be conceived within the scope of the technical ideas described in the claims, and it is understood that modifications or improvements thereto naturally belong to the technical scope of the present invention.

### INDUSTRIAL APPLICABILITY

It is possible to apply some embodiments of the present invention to a photoelectric converter, an X-ray detector, or the like in which it is necessary to reduce leakage current without reducing the ratio of an area of a silicon layer in a photodiode.

### REFERENCE SIGNS LIST

10: ELEMENT SUBSTRATE
13: GATE ELECTRODE
14: SOURCE ELECTRODE
15: DRAIN ELECTRODE
19: THIN FILM TRANSISTOR
24: FIRST CONTACT HOLE
24a, 27a: TAPERED PART
25: PHOTODIODE
26: LOWER LAYER ELECTRODE
27 SECOND CONTACT HOLE
27b STEP PORTION
33 BIAS LINE CONTACT HOLE
37 THIRD CONTACT HOLE
37 CONTACT HOLE
100 200 300 PHOTOELECTRIC CONVERTER
400 X-RAY DETECTOR
402 SCINTILLATOR
GL GATE BUS LINE
L1, L2, L3 OPENING WIDTH
SL SOURCE BUS LINE
t OPENING DEPTH

1. A photoelectric converter comprising:
an element substrate having
a photodiode and a thin film transistor arranged in matrix form,
an interlayer insulating film laminated on the thin film transistor,
a first contact hole formed in the interlayer insulating film and reaching a surface of a source electrode of the thin film transistor, and
a second contact hole formed in the interlayer insulating film and reaching a surface of a drain electrode of the thin film transistor,
wherein a source bus line and the source electrode of the thin film transistor are connected via the first contact hole,
the drain electrode of the thin film transistor and a lower layer electrode of the photodiode are connected via the second contact hole, and
a tapered part of the second contact hole has a gentler inclination than a tapered part of the first contact hole.

2. A photoelectric converter comprising:
an element substrate having
a photodiode and a thin film transistor arranged in matrix form,
an interlayer insulating film laminated on the thin film transistor,
a second contact hole formed in the interlayer insulating film and reaching a surface of a drain electrode of the thin film transistor, and
a third contact hole formed in the interlayer insulating film and reaching a surface of a gate electrode of the thin film transistor,
wherein the drain electrode of the thin film transistor and a lower layer electrode of the photodiode are connected via the second contact hole,
the gate electrode of the thin film transistor and a gate bus line are connected via the third contact hole, and
a tapered part of the second contact hole has a gentler inclination than a tapered part of the third contact hole.

3. The photoelectric converter according to claim 1,
wherein a tapered shape of the second contact hole is gently inclined by 1.5 times or more than a tapered shape of the first contact hole or the third contact hole.

4. The photoelectric converter according to claim 1,
wherein an inclination angle θ of the tapered part of the second contact hole is approximately 50° or less.

5. The photoelectric converter according to claim 1,
wherein the tapered part of the second contact hole has an aspect ratio of 2:1 for opening depth to opening width.

6. The photoelectric converter according to claim 1,
wherein a step portion is provided in a tapered shape of the second contact hole.

7. The photoelectric converter according to claim 1,
wherein the interlayer insulating film is a planarization layer having a film thickness of 1 μm or more.

8. The photoelectric converter according to claim 1,
wherein the interlayer insulating film is an organic insulating film.

9. (canceled)

10. The photoelectric converter according to claim 1,
wherein the thin film transistor overlaps the photodiode in plan view.

11. The photoelectric converter according to claim 1,
wherein a portion of the interlayer insulating film positioned between the thin film transistor and the photodiode is flat.

12. (canceled)

13. An X-ray detector comprising:
a scintillator which converts X-rays into visible light; and
the photoelectric converter according to claim 1.

14. The photoelectric converter according to claim 2,
wherein a tapered shape of the second contact hole is gently inclined by 1.5 times or more than a tapered shape of the first contact hole or the third contact hole.

15. The photoelectric converter according to claim 2,
wherein an inclination angle θ of the tapered part of the second contact hole is approximately 50° or less.

16. The photoelectric converter according to claim 2,
wherein the tapered part of the second contact hole has an aspect ratio of 2:1 for opening depth to opening width.

17. The photoelectric converter according to claim 2,
wherein a step portion is provided in a tapered shape of the second contact hole.

18. The photoelectric converter according to claim 2,
wherein the interlayer insulating film is a planarization layer having a film thickness of 1 μm or more.

19. The photoelectric converter according to claim 2,
wherein the interlayer insulating film is an organic insulating film.

20. The photoelectric converter according to claim 2,
wherein the thin film transistor overlaps the photodiode in plan view.

21. The photoelectric converter according to claim 2,
wherein a portion of the interlayer insulating film positioned between the thin film transistor and the photodiode is flat.

22. An X-ray detector comprising:
a scintillator which converts X-rays into visible light; and
the photoelectric converter according to claim 2.
